(19) United States
(12) Patent Application Publication
(10) Pub. No.: US 2026/0026374 A1
(43) Pub. Date: Jan. 22, 2026

(54) SEMICONDUCTOR PACKAGE HAVING INTERCONNECTABLE SUBSTRATES

(71) Applicant: Sandisk Technologies, Inc., Milpitas, CA (US)

(72) Inventors: Haoran Wu, Shanghai (CN); Chee Keong Chin, Shanghai (CN); Feng Luo, Shanghai (CN); JianHua Wang, Shanghai (CN); Yu Zheng, Shanghai (CN); Junrong Yan, Shanghai (CN)

(21) Appl. No.: 18/774,312

(22) Filed: Jul. 16, 2024

(51) Int. Cl. H01L 23/538; H01L 21/48; H01L 23/053; H01L 25/065

(52) U.S. Cl. CPC H01L 23/5382; H01L 21/485; H01L 23/053; H01L 23/5385; H01L 25/0655

(57) ABSTRACT

A semiconductor package includes a number of different substrate sections. Each substrate section includes one or more electronic components. Additionally, each substrate section is mechanically and electrically coupled together using various conductive columns and conductive apertures. Because the substrate sections are interconnectable, a shape and/or a size of the semiconductor package is fully customizable. Additionally, a layout of the various electronic components of the semiconductor package is also fully customizable.

### BACKGROUND

Semiconductor packages are used in various electronic devices such as cellular telephones, digital cameras, personal digital assistants, medical electronics, mobile computing devices, and the like. Because of its inclusion in most modern electronic devices, the demand for semiconductor packages is increasing. However, each electronic device has various semiconductor package requirements regarding size, capacity and/or performance.

Regardless of the size, capacity and/or performance requirements, a fundamental part of each semiconductor package is the substrate. The substrate is the base layer of each semiconductor package on which various electronic components are placed. For example, and depending on the type of semiconductor package that is being created, various electronic components (e.g., semiconductor dies, integrated circuits) are placed on and/or coupled to the substrate. However, there is typically very little flexibility when it comes to the size of the substrate and/or the layout of the various electronic components on the substrate.

Accordingly, it would be beneficial for a substrate of a semiconductor package to have design and layout flexibility depending on the type of semiconductor package being created and/or depending on design requirements of various electronic devices.

### SUMMARY

The present disclosure describes a semiconductor package having one or more interconnected substrates or substrate sections. As such, a size and/or a shape of a semiconductor package is completely customizable. In addition, each substrate section includes one or more electronic components. Because each substrate section is interconnectable with other substrate sections, the arrangement and/or layout of the various electronic components of the semiconductor package is completely customizable as well.

In an example, and as will be described in greater detail herein, each substrate section includes a first planar surface (e.g., a top planar surface) and a second planar surface (e.g., a bottom planar surface). A first ledge extends from a first lateral side of the substrate section such that the first ledge and the first planar surface have a first stairstep configuration. A number of conductive columns are provided on the first ledge.

Additionally, a second ledge extends from a second lateral side of the substrate section. In an example, the second ledge extends from the second lateral side of the substrate section such that the second ledge and the second planar surface have a second stairstep configuration. The second ledge also includes or defines a number of a number of conductive apertures.

In an example, the conductive columns and the conductive apertures enable the substrate section to be mechanically and/or electrically coupled to another substrate section. For example, the conductive columns on the first ledge of the substrate section are interconnectable with conductive apertures on a second ledge of another substrate section. Likewise, the conductive apertures on the second ledge of the substrate section are interconnectable with conductive columns on a first ledge of another substrate section. As a result, a semiconductor package can be formed in any desired shape and/or size.

The present disclosure also describes a three-dimensional (3D) printed enclosure for the semiconductor package. In an example, when two or more substrate sections are interconnected, a first boundary layer is 3D printed or otherwise formed around one or more of the substrate sections. A thermosetting liquid resin is provided in an area defined by the first boundary layer. When the thermosetting liquid resin has cured, a second boundary layer is 3D printed on the first boundary layer. Another layer of thermosetting liquid resin is provided in the area defined by the second boundary layer. This process repeats until some or all of the electronic components are enclosed or surrounded by the thermosetting liquid resin.

Accordingly, examples of the present disclosure describe a semiconductor package that includes a substrate and at least one electronic component. In an example, the substrate includes a first planar surface and a second planar surface opposite the first planar surface. A first ledge extends from a first lateral side of the substrate. In an example, the first ledge and the first planar surface form a first stairstep configuration. A plurality of conductive columns are provided on the first ledge. The substrate also includes a second ledge extending from a second lateral side of the substrate. In an example, the second ledge and the second planar surface form a second stairstep configuration. A plurality of conductive apertures are provided in the second ledge. The at least one electronic component is electrically coupled to at least one of the first planar surface and the second planar surface.

Other examples describe a method for creating a semiconductor package. In an example, the method includes providing a first substrate section having a plurality conductive columns on a first lateral side and providing a second substrate section having a plurality of conductive apertures on a second lateral edge. The first substrate section and the second substrate section are interconnected by inserting the plurality of conductive columns on the first lateral side of the first substrate section into the plurality of conductive apertures on the second lateral side of the second substrate section.

Examples also describe a semiconductor package that includes a substrate and at least one electronic component electrically coupled to the substrate. In an example, the substrate has a first ledge extending from a first lateral side. The first ledge and a first planar surface of the substrate form a first stairstep portion. In an example, a plurality of first interconnection means extend from the first ledge. A second ledge extends from a second lateral side of the substrate. The second ledge and a second planar surface of the substrate form a second stairstep portion. In an example, a plurality of second interconnection means are provided in the second ledge.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates a substrate section according to an example.

FIG. 1B illustrates the substrate section of FIG. 1A interconnected with other substrate sections according to an example.

FIG. 2A illustrates a plurality of conductive columns extending from a first ledge of the substrate section of FIG. 1A according to an example.

FIG. 2B illustrates a plurality of conductive apertures defined by the second ledge of the substrate section of FIG. 1A according to an example.

FIG. 3A illustrates a substrate section according to another example.

FIG. 3B illustrates the substrate section of FIG. 3A interconnected with other substrate sections according to an example.

FIG. 4 illustrates a substrate section having a first electronic component communicatively coupled to conductive column and a second electronic component communicatively coupled to a conductive aperture according to an example.

FIG. 5 illustrates a semiconductor package that is comprised of multiple substrate sections, with each substrate section having a number of electronic components according to an example.

FIG. 6A illustrates a semiconductor package according to another example.

FIG. 6B illustrates how electronic components of the semiconductor package of FIG. 6A are at least partially encapsulated according to an example.

FIG. 6C illustrates the semiconductor package of FIG. 6B in which a second boundary layer has been formed using a first 3D printing process and a first encapsulation layer has been formed using a second 3D printing process according to an example.

FIG. 6D illustrates how multiple 3D printing processes form an enclosure for the semiconductor package of FIG. 6C according to an example.

FIG. 6E illustrates how a marking is formed on a top surface of the enclosure of FIG. 6D according to an example.

FIG. 7 illustrates a method for creating a semiconductor package according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

Most semiconductor packages include various electronic components, integrated circuits and/or semiconductor dies mounted on a substrate. However, the shape and/or size of the substrate and/or a layout of the various electronic components, integrated circuits and/or semiconductor dies within the semiconductor package is typically fixed. As such, when a semiconductor package having a different size and/or shape is needed and/or when a different layout of the electronic components on the substrate is desired, a completely new semiconductor package typically needs to be designed. However, designing a new semiconductor package with a new substrate size and/or shape and/or a new electronic component layout is time intensive and expensive.

To address the above, the present disclosure describes a substrate for a semiconductor package that is interconnectable with other substrates. For example, a first substrate (or substrate section) can be snap-fit together with a second substrate (or substrate section). As such, a size and/or a shape of a substrate layer of a semiconductor package is completely customizable.

In some examples, each substrate section includes one or more electronic components. Because each substrate section is interconnectable with other substrate sections, the arrangement and/or layout of the various electronic components of the semiconductor package is also completely customizable.

As will be described in greater detail, each substrate section includes a first planar surface and a second planar surface. A first ledge extends from a first lateral side of the substrate section such that the first ledge and the first planar surface have a first stairstep configuration. A second ledge extends from a second lateral side of the substrate section such that the second ledge and the second planar surface have a second stairstep configuration.

A number of conductive columns are provided on the first ledge and a number of conductive apertures are defined in the second ledge. The conductive columns and the conductive apertures enable the substrate section to be electrically and/or communicatively coupled to another substrate section.

For example, the conductive columns on the first ledge of the substrate section are interconnectable with conductive apertures on a second ledge of another substrate section. Likewise, the conductive apertures on the second ledge of the substrate section are interconnectable with conductive columns on a first ledge of another substrate section. As a result, a semiconductor package can be formed in any desired shape and/or size.

The semiconductor package also includes a three-dimensional (3D) printed enclosure. The 3D printed enclosure is comprised of a number of different layers. For example, a first boundary layer is 3D printed (using a first 3D printing process) on a perimeter of one or more substrate sections. A second 3D printing process is used to form an encapsulation layer within the first boundary layer. For example, a thermosetting liquid resin is provided in an area defined by the first boundary layer.

When the thermosetting liquid resin has cured (e.g., using an ultraviolet (UV) light), a second boundary layer is 3D printed on the first boundary layer. Another layer of thermosetting liquid resin is provided in an area defined by the second boundary layer and the process repeats until the enclosure is completely formed. When the enclosure is formed, various markings may be 3D printed on a top surface of the enclosure. As such, the need for separate machines, such as a molding machine to form the enclosure, and a laser to form a marking on the enclosure, is eliminated.

Accordingly, many technical benefits may be realized including, but not limited to, enabling semiconductor packages to be fully customizable without requiring a new semiconductor package to be designed from the ground up; enabling a semiconductor package to have a variety of different shapes, sizes and configurations based on requirements of an electronic device in which the semiconductor package will be placed, and simplifying the encapsulation process by enabling an enclosure to be formed by a single machine (when compared to current processes which require multiple machines for form and mark and enclosure).

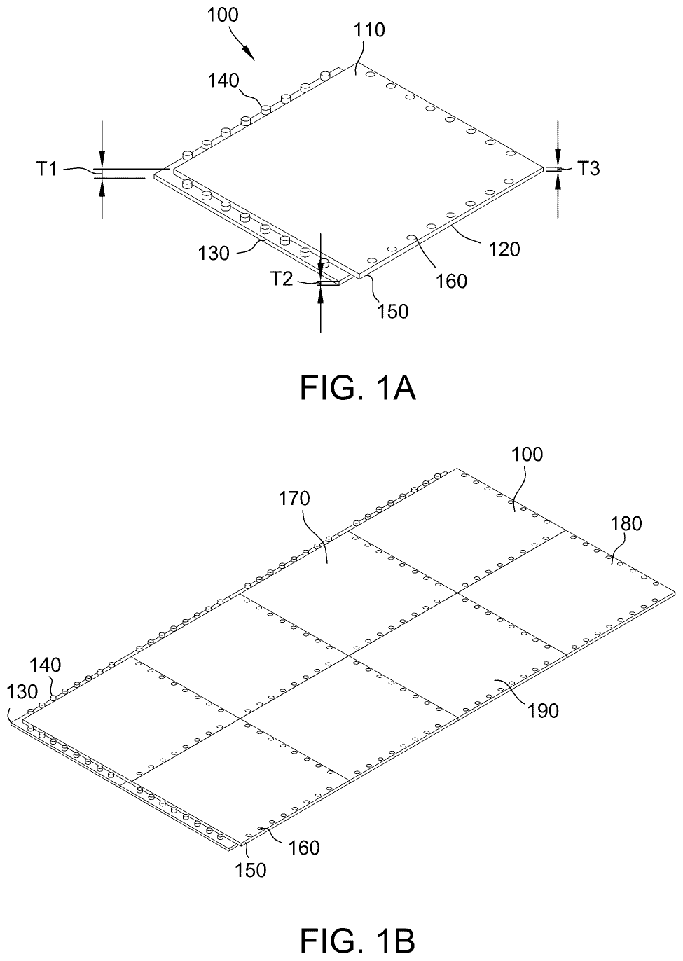

These and other examples will be described in more detail with respect to FIG. 1A

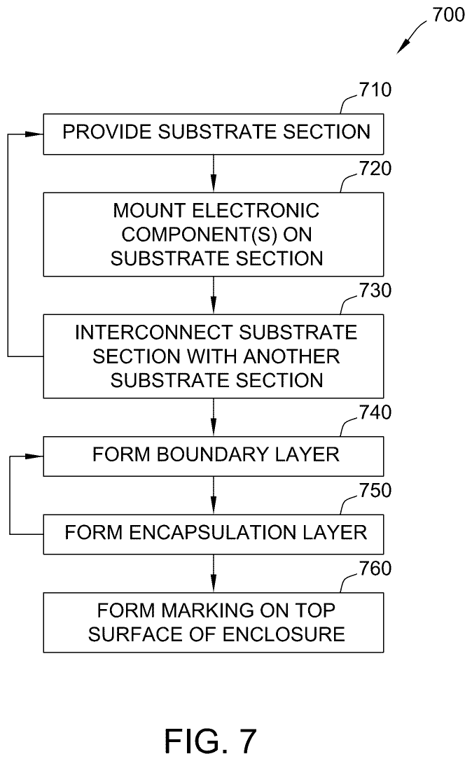

FIG. 7.

FIG. 1A illustrates a substrate section 100 according to an example. In an example, the substrate section 100 is formed from any suitable material or material composition that includes semiconducting properties/characteristics. In an example, the substrate section 100 includes various layers. For example, the substrate section 100 includes a first layer comprised of a non-conducting material and a second layer comprised of a conducting material. Although two layers are specifically mentioned, the substrate section 100 can include any number of different layers.

The substrate section 100 includes a first planar surface 110 and a second planar surface 120 opposite the first planar surface 110. The first planar surface 110 and the second planar surface 120 define a thickness T1. The thickness T1 is based, at least in part, on a number and/or type of layers of the substrate section 100.

The substrate section 100 includes a number of lateral sides or edges. The number of lateral sides is based, at least in part, on a shape of the substrate section 100. In the example shown in FIG. 1A, the substrate section 100 has a square shape. As such, the substrate section 100 has four lateral sides. Although the substrate section 100 has a square shape in FIG. 1A, it is contemplated that the substrate section 100 may have any shape including, but not limited to, triangular, rectangular, circular, octagonal, trapezoidal, etc.

A first ledge 130 extends from a first lateral side of the substrate section 100. For example, the first ledge 130 extends from (or is part of) the second planar surface 120. The first ledge 130 has a second thickness T2 that is less than the first thickness T1. As such, the substrate section 100 has a first stairstep configuration with respect to the first planar surface 110 and the first ledge 130. For example, the first planar surface 110 and the first ledge 130 form a first stairstep portion.

In an example, the first ledge 130 extends completely across the first lateral side. In another example, the first ledge 130 extends continuously across a first lateral side and at least one other lateral side. In another example, the first ledge 130 extends at least partially across the first lateral side and/or across at least one other lateral side. In yet another example, the first ledge 130 extends partially or entirely across more than two lateral sides of the substrate section 100.

In an example, a plurality of conductive columns 140 are provided on and/or extend from the first ledge 130. In an example, the conductive columns 140 are circular. Although circular conductive columns 140 are shown and described, the conductive columns 140 may have any shape. The conductive columns 140 have a height or a thickness equivalent to T1 minus T2. As such, a top surface of each conductive column 140 is aligned with the first planar surface 110 of the substrate section 100. In other examples, the height or thickness of the conductive columns 140 is greater than T1 minus T2 or less than T1 minus T2.

Each conductive column 140 is made of, or has a layer (e.g., an outer layer) of, a conductive material. For example, the conductive column 140 has an outer layer of (or is made of), copper, silver, gold or other such conductive material. As will be explained in greater detail herein, the conductive columns 140 enable the substrate section 100 to be interconnected (mechanically and/or electrically) with other substrate sections 100.

The substrate section 100 also includes a second ledge 150. The second ledge 150 extends from a second lateral side of the substrate section 100. For example, the second ledge 150 extends from (or is part of) the first planar surface 110. As such, the substrate section 100 has a second stairstep configuration (or a second stairstep portion) with respect to the second planar surface 120 and the second ledge 150.

The second ledge 150 has a third thickness T3 that is less than the first thickness T1. In an example, the thickness T2 of the second ledge 150 is equivalent to the thickness T1 of the first ledge 130. Additionally, in an example, T2+T3=T1.

In an example, the second ledge 150 extends completely across the second lateral side of the substrate section 100. In another example, the second ledge 150 extends continuously across the second lateral side and another lateral side. In another example, the second ledge 150 extends at least partially across the second lateral side and/or another lateral side. In yet another example, the second ledge 150 extends partially or entirely across more than two lateral sides.

In an example, a plurality of conductive apertures 160 are defined by and/or are provided in the second ledge 150. In an example, the conductive apertures 160 are circular. Although circular conductive apertures 160 are shown and described, the conductive apertures 160 may have any shape-provided the conductive apertures 160 match a shape of the conductive columns 140 to which they will be connected.

In an example, the conductive apertures 160 extend entirely through the second ledge 150. In another example, the conductive apertures 160 extend partially through the second ledge 150. In yet another example a depth of the conductive apertures 160 is equivalent to the height and/or the thickness of the conductive columns 140.

Each conductive aperture 160 is made of, or is layered with, a conductive material. For example, an inner surface of each conductive aperture 160 includes a layer of copper, silver, gold or other such conductive material. As will be explained in greater detail herein, the conductive apertures 160 enable the substrate section 100 to be interconnected (mechanically and/or electrically) with other substrate sections 100.

FIG. 1B illustrates the substrate section 100 of FIG. 1A interconnected with other substrate sections according to an example. As shown in FIG. 1B, eight substrate sections 100 are interconnected to form a rectangle. Although eight substrate sections 100 and a rectangle are shown and described, any number of substrate sections 100 can be interconnected to form a variety of different shapes and/or sizes.

In an example, the substrate section 100 (also referred to as a first substrate section) is electrically and/or mechanically interconnected with a second substrate section 170 and a third substrate section 180 via the conductive columns 140 and the conductive apertures 160. For example, conductive columns 140 on a first lateral side of the first substrate section are inserted into conductive apertures 160 on a second lateral side of the second substrate section 170. Likewise, conductive apertures 160 on a second lateral side of the first substrate section receive conductive columns 140 on a first lateral side of a third substrate section 180. In this example, a fourth substrate section 190 is interconnected with the second substrate section 170 and the third substrate section 180 in a similar manner.

In an example, lateral sides of one or more of the substrate sections 100 that are not mechanically and/or communicatively coupled to other substrate sections, include a cover or a portion that fits on, in and/or over the unconnected ledges. For example, the cover is comprised of a substrate (or other material) that covers exposed or unconnected conductive columns 140 and/or conductive apertures 160.

In one example, the cover includes non-conductive (or conductive) columns that fit within exposed conductive apertures 160. In another example, the cover includes non-conductive (or conductive) apertures that receive exposed conductive columns 140. In an example, the cover has a width that matches or is equivalent to a width of the first ledge 130 and/or the second ledge 150. Additionally, the cover has a thickness that is equivalent to the thickness T1 minus T2 (or T1 minus T3).

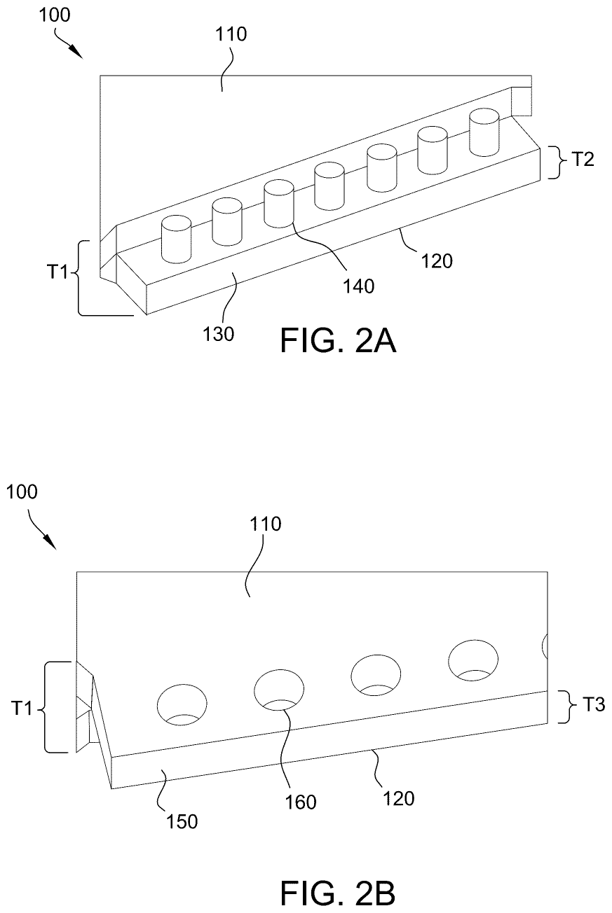

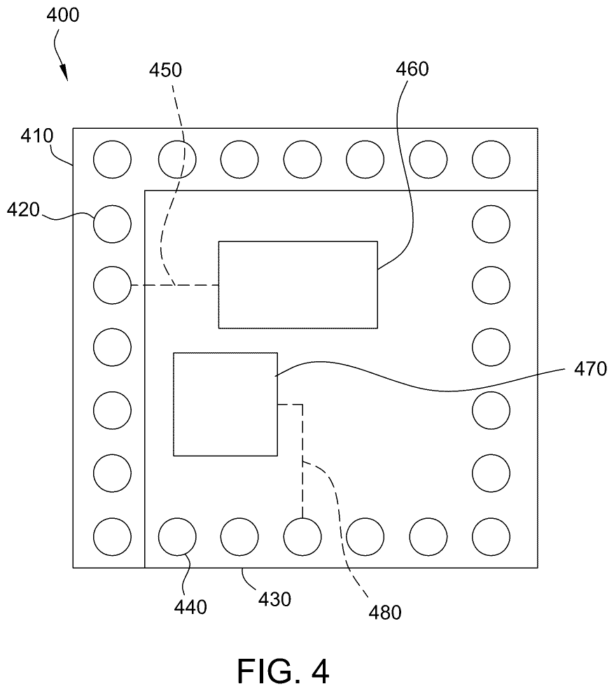

FIG. 2A illustrates a plurality of conductive columns 140 extending from a first ledge 130 of the substrate section 100 of FIG. 1A according to an example. In an example, each conductive column 140 includes, or is comprised of, a conductive material. In addition, one or more traces (e.g., a first trace 450 (FIG. 4)) extend from each conductive column 140 and may be used to electrically couple the substrate section 100 to other substrate sections, to electrically couple electronic components on the substrate section 100 to other electronic components on other substrate sections and/or to electrically couple electronic components to one or more solder pads and/or solder bumps on the substrate section.

In an example and as previously described, the first ledge 130 extends from, or is part of, the second planar surface 120 of the substrate section 100. As such, a first stairstep portion is formed between the first planar surface 110 and the first ledge 130. As also previously described, in an example, the first ledge 130 has a thickness T2 that is less than a thickness T1 of the substrate section 100.

FIG. 2B illustrates a plurality of conductive apertures 160 defined by the second ledge 150 of the substrate section 100 of FIG. 1A according to an example. In an example, each conductive aperture 160 includes or is comprised of a conductive material. In addition, one or more traces (e.g., a second trace 480 (FIG. 4)) extend from each conductive aperture 160 and may be used to electrically couple the substrate section 100 to other substrate sections, to electrically couple electronic components on the substrate section 100 to other electronic components on other substrate sections and/or to electrically couple electronic components to one or more solder pads and/or solder bumps on the substrate section.

In an example and as previously described, the second ledge 150 extends from, or is part of, the first planar surface 110 of the substrate section 100. As such, a second stairstep portion is formed between the second planar surface 120 and the second ledge 150. As also previously described, in an example, the second ledge 150 has a thickness T3 that is less than a thickness T1 of the substrate section 100.

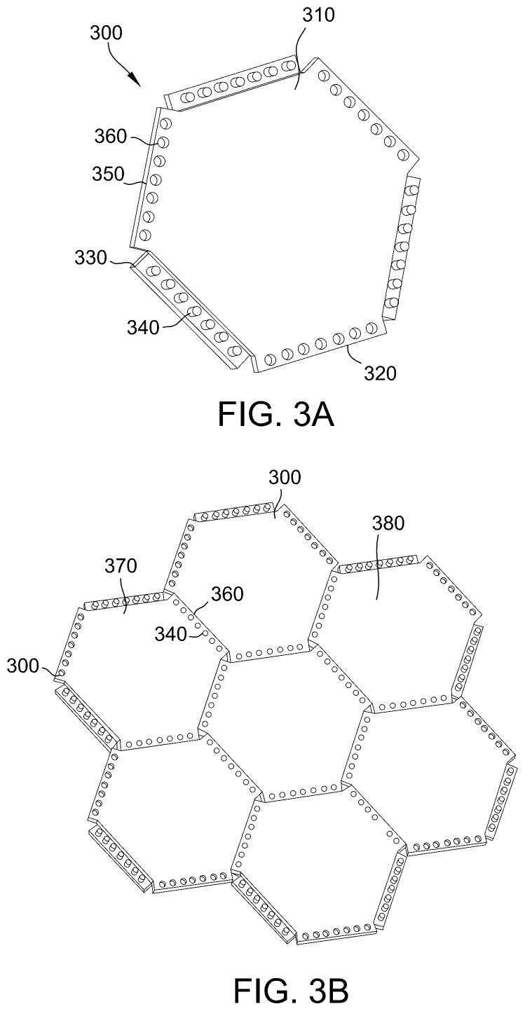

FIG. 3A illustrates a substrate section 300 according to another example. Like the substrate section 100 shown and described with respect to FIG. 1A, the substrate section 300 includes a first planar surface 310 and a second planar surface 320 opposite the first planar surface 110. The first planar surface 310 and the second planar surface 320 define a thickness such as previously described.

The substrate section 300 includes a number of lateral sides or edges. In this example, the substrate section 300 is hexagonal shaped. As such, the substrate section 300 has six lateral sides.

In an example, a first ledge 330 extends from a first lateral side of the substrate section 300 and a second ledge 350 extends from a second lateral side of the substrate section 300. A plurality of conductive columns 340 are provided on and/or extend from the first ledge 330 and a plurality of conductive apertures 360 are defined by, or are otherwise provide on, the second ledge 350. In an example, each lateral side of the substrate section 300 alternates between having conductive columns 340 and conductive apertures 360—although this is not required.

In an example, the first ledge 330, the conductive columns 340, the second ledge 350 and the conductive apertures 360 are formed and/or function in a manner that is similar to the first ledge 130, the conductive columns 140, the second ledge 150 and the conductive apertures 160 shown and described above with respect to FIG. 1A.

FIG. 3B illustrates the substrate section 300 of FIG. 3A interconnected with other substrate sections according to an example. As shown in FIG. 3B, seven substrate sections 300 are interconnected to form a single substrate portion having a specific shape and size. Although seven substrate sections 300 are shown and described, any number of substrate sections 300 can be interconnected to form a variety of different shapes and/or sizes.

Like the example shown and described with respect to FIG. 1B, the substrate section 300 (also referred to as a first substrate section) is electrically and/or mechanically interconnected with a second substrate section 370 and a third substrate section 380 via conductive columns 340 and conductive apertures 360. For example, conductive columns 340 on a first lateral side of the first substrate section are inserted into conductive apertures 360 on a second lateral side of the second substrate section 370. Likewise, conductive apertures 360 on a second lateral side of the first substrate section receive conductive columns 340 on a first lateral side of a third substrate section 380.

FIG. 4 illustrates a substrate section 400 having a first electronic component 460 communicatively coupled to conductive column 420 and a second electronic component 470 communicatively coupled to a conductive aperture 440 according to an example. In an example, the substrate section 400 is similar to the substrate section 100 shown and described with respect to FIG. 1A.

For example, the substrate section 400 includes a first planar surface and a second planar surface. A plurality of conductive columns 420 are provided on a first ledge 410. Likewise, a plurality of conductive apertures 440 are defined by, or are provided on, a second ledge 430.

In addition, a first electronic component 460 and a second electronic component 470 are placed on and/or coupled to the first planar surface of the substrate section 400. A first trace 450 electrically couples at least one conductive column 420 to the first electronic component 460 and a second trace 480 electrically couples the second electronic component 470 to at least one conductive aperture 440. Although traces are specifically mentioned, the substrate section 400 may include one or more conductive layers, through silicon vias (TSVs), or other conductive pathways/communication channels to electrically couple the substrate section 400 to other substrate sections and/or to electrically couple various electronic components to each other and/or to a printed circuit board (PCB).

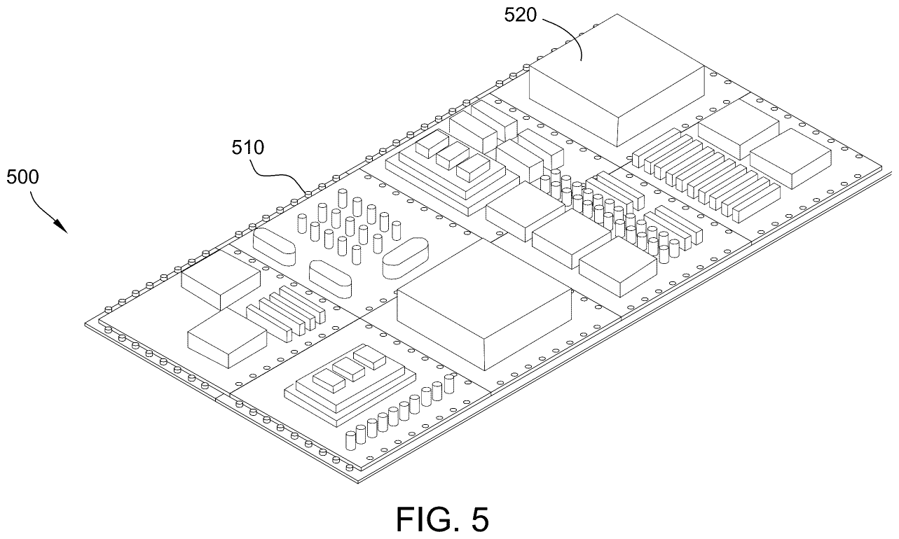

FIG. 5 illustrates a semiconductor package 500 that is comprised of multiple substrate sections 510 with each substrate section having a number of electronic components 520 according to an example. In an example, each substrate section 510 of the semiconductor package 500 is similar to the substrate section 100 shown and described with respect to FIG. 1A.

As shown in FIG. 5, the semiconductor package 500 includes eight substrate sections 510. In an example, each substrate section 510 includes various electronic components 520. For example, a first substrate section 510 includes a first type of electronic component having a first type of functionality while a second substrate section 510 includes a second type of electronic component 520 having a second type of functionality. In another example, one or more substrate sections include the same electronic components or similar electronic components.

In an example, two or more substrate sections 510 are interconnected in a manner as previously described. Once the two or more substrate sections have been interconnected, the various electronic components 520 are surface mounted on, and/or are electrically coupled to, a surface of each substrate section 510. In another example, electronic components 520 are mounted on a particular substrate section 510. Once each electronic component 520 is mounted on and/or electrically coupled to a particular substrate section 510, the electronic components and/or the substrate section 510 is tested to determine if it functions properly. If so, the substrate section 510 is mechanically and/or electrically coupled to another substrate section 510 to form the semiconductor package 500.

Although a specific layout of the substrate sections 510 and the electronic components 520 are shown, it is contemplated that each substrate section 510 can be rearranged or positioned differently with respect to each of the other substrate sections to achieve a different layout. For example, in a first layout, a first substrate section 510 and its associated electronic components 520 are adjacent a second substrate section 510 and its associated electronic components 520 and a third substrate section 510 and its associated electronic components. However, in a second layout, the first substrate section 510 is adjacent a fourth substrate section 510 and its associated electronic components 520 and an eighth substrate section 510 and its associated electronic components 520.

In yet another example, a substrate section 510 may have a first orientation in a first semiconductor package 500 and a second orientation in a second semiconductor package 500. For example, when comparing the first orientation of the substrate section 510 in the first semiconductor package 500 to the second orientation of the substrate section 510 in the second semiconductor package, the substrate section 510 may be rotated forty-five degrees (or more) when in the second orientation when compared with the first orientation.

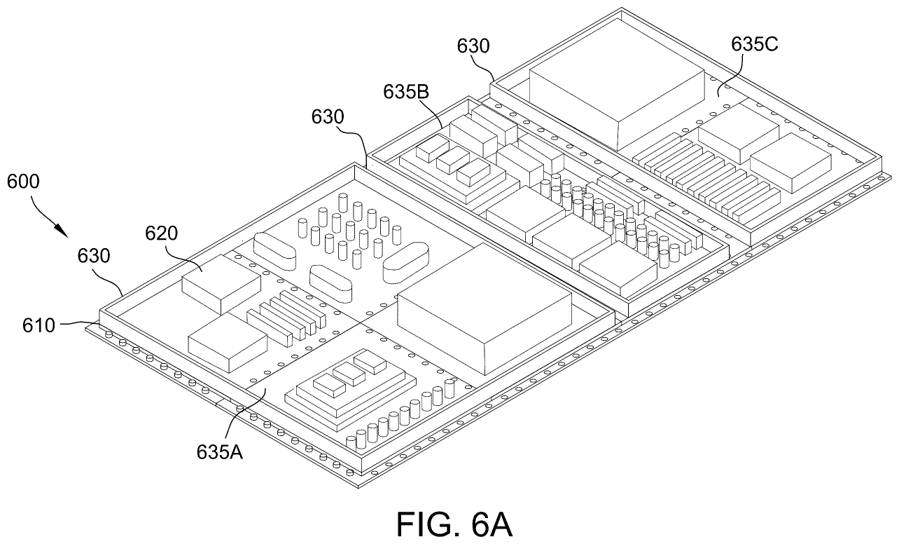

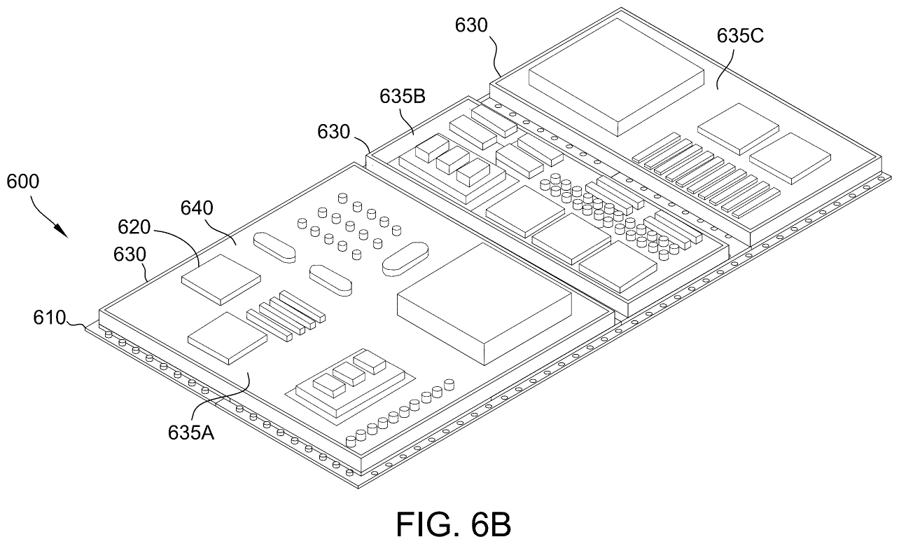

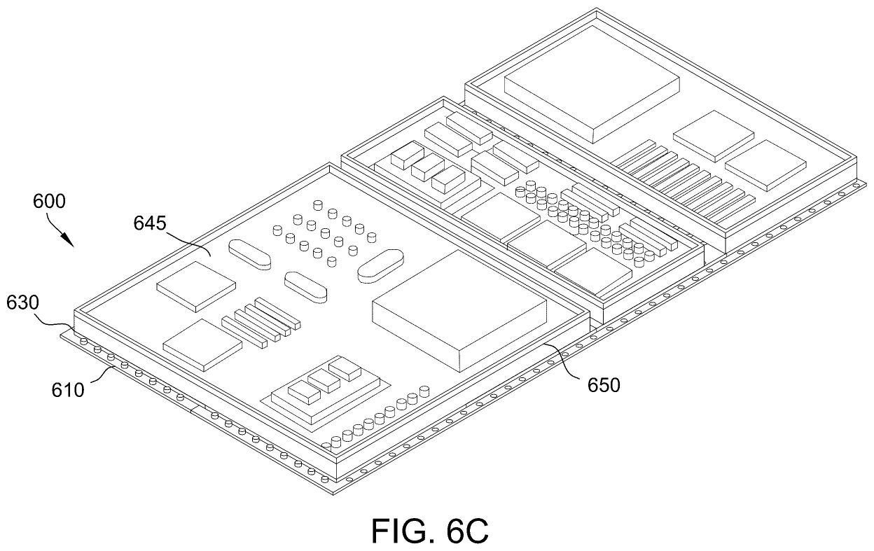

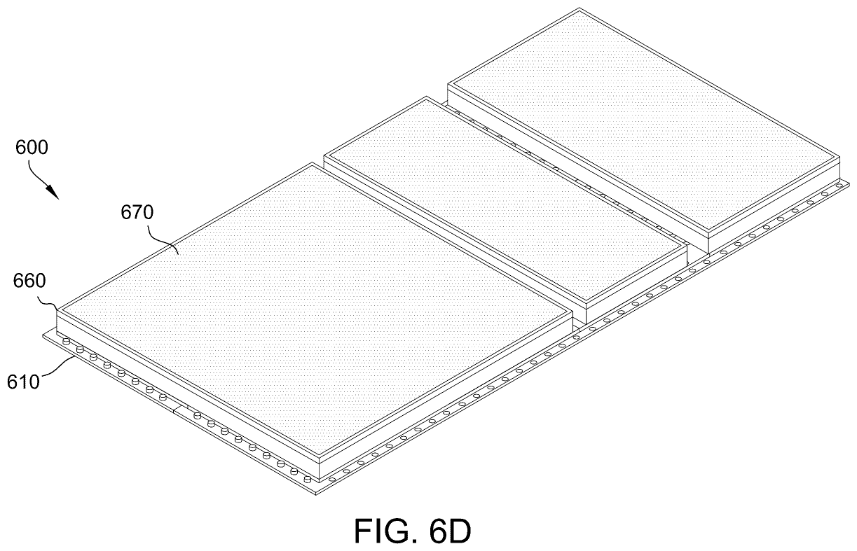

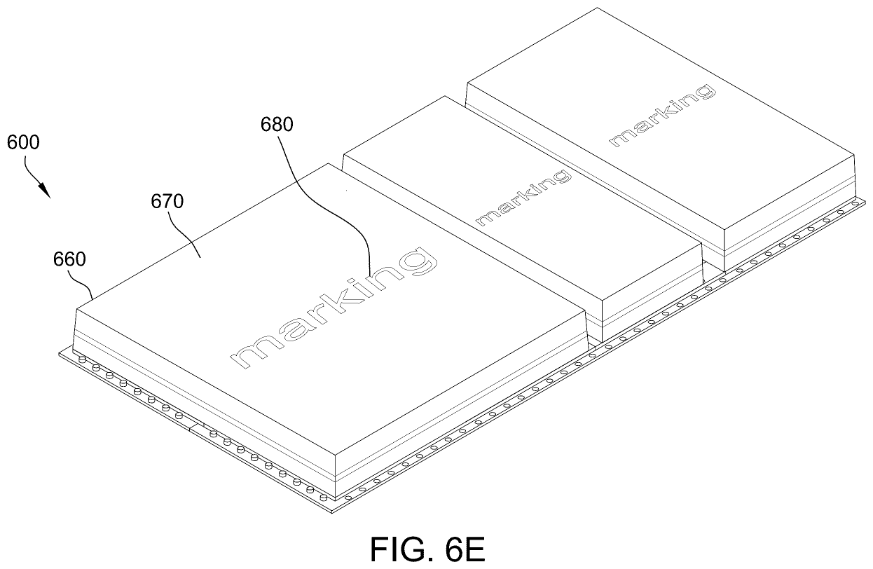

FIG. 6A-FIG. 6E illustrate how an enclosure (e.g., enclosure 660 (FIG. 6D)) is formed on a semiconductor package 600. In an example, the enclosure is formed using various three-dimensional printing processes or techniques. For example a boundary 630 of the enclosure is formed by a first 3D printing technique or process while an area defined by the boundary is enclosed or encapsulated using a second 3D printing technique and/or process.

For example and referring to FIG. 6A, FIG. 6A illustrates a semiconductor package 600 according to another example. In an example, the semiconductor package 600 is similar to the semiconductor package 500 shown and described with respect to FIG. 5. For example, the semiconductor package 600 includes a number of interconnected substrate sections 610 and each substrate section 610 includes one or more electronic components 620.

In this example, a first boundary layer 630 is 3D printed at least partially around a perimeter of at least one substrate section 610. In an example, the first boundary layer 630 is 3D printed using a first 3D printing process (e.g., a 3D printing process that uses filament). In the example shown in FIG. 6A, three different first boundary layers 630 are formed around different substrate sections 610. In an example, each first boundary layer 630 defines an area. For example, one first boundary layer 630 defines a first area 635A, one first boundary layer 630 defines a second area 635B, one first boundary layer 630 defines a third area 635C. Although three different first boundary layers 630 and areas are shown and described, this is for example purposes only.

FIG. 6B illustrates how the electronic components 620 of the semiconductor package 600 of FIG. 6A are at least partially encapsulated according to an example. In an example, the electronic components 620 of the semiconductor package 600 are at least partially encapsulated using a second 3D printing technique and/or process.

For example, a thermosetting liquid resin 640 is provided in each area defined by the first boundary layer 630. For example, when the first boundary layer 630 is 3D printed around a perimeter of at least one substrate section 610 using the first 3D printing process, the thermosetting liquid resin 640 is inserted into the first area 635A, the second area 635B and the third area 635C using a second 3D printing process.

In an example, and due to the viscosity of the thermosetting liquid resin, the thermosetting liquid resin flows into and/or within various cavities and/or tunnels that are present on and/or under the various electronic components 620. For example, if the electronic components 620 are a stack of NAND memory dies that are placed on a controller and/or on a spacer, the thermosetting liquid resin 640 may freely flow beneath the NAND memory dies and/or between the spacer and the controller to fill any gaps that may be present.

When the thermosetting liquid resin has been disposed in each of the areas, the thermosetting liquid resin is cured to form a first encapsulation layer. In an example, the thermosetting liquid resin is cured using a UV light or other light source.

FIG. 6C illustrates the semiconductor package 600 of FIG. 6B in which a second boundary layer has been formed using a first 3D printing process and a first encapsulation layer 645 has been formed using a second 3D printing process according to an example.

As shown in FIG. 6C, the thermosetting liquid resin has been cured to form the first encapsulation layer 645. When the first encapsulation layer 645 has been formed, the first 3D printing process is used to form a second boundary layer 650. In an example, the second boundary layer 650 is formed on top of, and/or over the first boundary layer 630. In an example, a pattern and/or shape of the second boundary layer 650 is the same as the first boundary layer 630 although this is not required.

For example, the first boundary layer 630 may be formed around a first set of electronic components 620 and/or a first substrate section 610 (or sections) and a second boundary layer 650 may be formed around a second set of electronic components 620 and/or a second substrate sections 610 (or sections). As such, an enclosure may have a variety of different heights and/or shapes depending on, for example a number and/or height of electronic components 620 on each substrate section 610.

When the second boundary layer 650 has been 3D printed on the first boundary layer 630, the thermosetting liquid resin is applied to each area defined by the second boundary layer 650. The thermosetting liquid resin is cured to form a second encapsulation layer. In an example, the process of forming additional boundary layers using the first 3D printing process and forming additional encapsulation layers using the second 3D printing process is repeated until the electronic components 620 are entirely encapsulated.

FIG. 6D illustrate how multiple 3D printing processes form an enclosure 660 for the semiconductor package 600 of FIG. 6C according to an example. For example, and as shown in FIG. 6D, each 3D printing process is used to form multiple boundary layers and multiple encapsulation layers. As a result, the enclosure 660 includes many different boundary layers and enclosure layers and the last boundary layer and/or enclosure layer form a top surface 670 of the enclosure.

FIG. 6E illustrates how a marking 680 is formed on a top surface 670 of the enclosure 660 of FIG. 6D according to an example. In an example, the marking 680 is formed on the top surface 670 of the enclosure 660 using the first 3D printing process. In another example, the marking 680 is formed using any other 3D printing process and/or marking process.

However, in some examples, the enclosure 660 and the marking 680 formed on the top surface 670 of the enclosure 660 are formed by a single machine. Thus, unlike traditional encapsulation and marking process that require two separate machines (e.g., a molding machine to form the enclosure and a laser to form the marking), the enclosure 660 of the present disclosure is formable by a single machine. As such, the time and/or cost involved in forming the enclosure 660 is substantially reduced when compared with current processes.

FIG. 7 illustrates a method 700 for creating a semiconductor package according to an example. In an example, the method 700 is used to create the semiconductor package 600 shown and described with respect to FIG. 6A-FIG. 6E.

In an example, the method 700 begins when a substrate section is provided (710). In an example, the substrate section is similar to the substrate section 100 shown and described with respect to FIG. 1A and/or the substrate section 300 shown and described with respect to FIG. 3A.

When the substrate section has been provided, one or more electronic components are mounted (720) on the substrate section. In an example, mounting the one or more electronic components on the substrate section includes electrically and/or communicatively coupling the one or more electronic components to various bond pads, traces, TSVs, etc., provided on or in the substrate section.

In an example, when the electronic components have been mounted on a substrate section, the substrate section is interconnected with another substrate section (e.g., a substrate section having the same or similar electronic components or different electronic components). In some examples, operations 720 and 730 may be executed multiple times and/or in a different order. For example, operation 730 may follow operation 710 and each operation may be repeated a number of times. After which, operation 720 is performed one or more times.

In an example, when two or more substrate sections have been interconnected, a boundary layer is formed (740) on at least a portion of at least one of the substrate sections. In an example, the boundary layer is formed on a perimeter of the at least one substrate section. Additionally, the first boundary layer is formed using a first 3D printing process.

When the boundary layer has been formed, an encapsulation layer is formed (750). In an example, the encapsulation layer is formed using a second 3D printing process that is different from the first 3D printing process. For example, the encapsulation layer is formed by inserting a thermosetting liquid resin into an area defined by the boundary layer. The thermosetting liquid resin is then cured such as previously described.

In an example, operations 740 and 750 are repeated any number of times until an enclosure is formed and/or until the electronic components are completely encapsulated by the thermosetting liquid resin.

When the enclosure is completed, a marking is formed (760) on a top surface of the enclosure. In an example, the marking is formed using the first 3D printing process.

Accordingly, examples described herein are directed to a semiconductor package, comprising: a substrate, comprising: a first planar surface; a second planar surface opposite the first planar surface; a first ledge extending from a first lateral side of the substrate, the first ledge and the first planar surface forming a first stairstep configuration; a plurality of conductive columns provided on the first ledge; a second ledge extending from a second lateral side of the substrate, the second ledge and the second planar surface forming a second stairstep configuration; and a plurality of conductive apertures defined by the second ledge; and at least one electronic component electrically coupled to at least one of the first planar surface and the second planar surface. In an example, the semiconductor package also includes at least one trace extending from at least one conductive column of the plurality of conductive columns. In an example, the semiconductor package also includes at least one trace extending from at least one conductive aperture of the plurality of conductive apertures. In an example, the at least one conductive aperture includes a conductive layer. In an example, the substrate is a first substrate and wherein the semiconductor package further comprises: a second substrate, comprising: a third planar surface; a fourth planar surface opposite the third planar surface; a third ledge extending from a first lateral side of the second substrate, the third ledge and the third planar surface forming a third stairstep configuration; a plurality of conductive columns provided on the third ledge; a fourth ledge extending from a second lateral side of the second substrate, the fourth ledge and the fourth planar surface forming a fourth stairstep configuration; and a plurality of conductive apertures defined by the fourth ledge. In an example, the plurality of conductive apertures defined by the fourth ledge of the second substrate are mechanically connected and electrically connected to the plurality of conductive columns provided on the first ledge of the first substrate. In an example, the plurality of conductive apertures defined by the second ledge of the first substrate are mechanically connected and electrically connected to the plurality of conductive columns provided on the third ledge of the second substrate. In an example, the semiconductor package also includes at least one electronic component electrically coupled to at least one of the third planar surface and the fourth planar surface. In an example, the at least one electronic component electrically coupled to the at least one of the first planar surface and the second planar surface is a first type of electronic component and wherein the at least one electronic component electrically coupled to the at least one of the third planar surface and fourth planar surface is a second type of electronic component. In an example, the at least one electronic component electrically coupled to the at least one of the first planar surface and the second planar surface is electrically coupled to the at least one electronic component electrically coupled to the at least one of the third planar surface and fourth planar surface.

Examples also describe a method, comprising: providing a first substrate section having a plurality conductive columns on a first lateral side; providing a second substrate section having a plurality of conductive apertures defined by a second lateral side; and interconnecting the first substrate section and the second substrate section by inserting the plurality of conductive columns on the first lateral side of the first substrate section into the plurality of conductive apertures defined by the second lateral side of the second substrate section. In an example, the first substrate section has a first electronic component and the second substrate section has a second electronic component. In an example, the first electronic component is a first type of electronic component and the second electronic component is a second type of electric component that is different from the first type of electronic component. In an example, the first electronic component is electrically coupled to the second electronic component. In an example, the plurality of conductive columns is comprised of a first conducting layer and wherein the plurality of conductive apertures is comprised of a second conducting layer.

Examples also describe a semiconductor package, comprising: a substrate, comprising: a first ledge extending from a first lateral side, the first ledge and a first planar surface forming a first stairstep portion; a plurality of first interconnection means extending from the first ledge; a second ledge extending from a second lateral side, the second ledge and a second planar surface forming a second stairstep portion; and a plurality of second interconnection means defined by the second ledge; and at least one electronic component electrically coupled to the substrate. In an example, the semiconductor package also includes a three-dimensional (3D) printed enclosure means at least partially enclosing the at least one electronic component. In an example, the semiconductor package also includes at least one signal routing means extending from at least one of the plurality of first interconnection means. In an example, the semiconductor package also includes at least one signal routing means extending from at least one of the plurality of second interconnection means. In an example, the substrate is a first substrate and the semiconductor package further comprises a second substrate, the second substrate comprising: a third planar surface; a fourth planar surface opposite the third planar surface; a third ledge extending from a first lateral side of the second substrate, the third ledge and the third planar surface forming a third stairstep configuration; a plurality of conductive columns provided on the third ledge; a fourth ledge extending from a second lateral side of the second substrate, the fourth ledge and the fourth planar surface forming a fourth stairstep configuration; and a plurality of conductive apertures defined by the fourth ledge.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a substrate, comprising:
a first planar surface;
a second planar surface opposite the first planar surface;
a first ledge extending from a first lateral side of the substrate, the first ledge and the first planar surface forming a first stairstep configuration;
a plurality of conductive columns provided on the first ledge;
a second ledge extending from a second lateral side of the substrate, the second ledge and the second planar surface forming a second stairstep configuration; and
a plurality of conductive apertures defined by the second ledge; and
at least one electronic component electrically coupled to at least one of the first planar surface and the second planar surface.

2. The semiconductor package of claim 1, further comprising at least one trace extending from at least one conductive column of the plurality of conductive columns.

3. The semiconductor package of claim 1, further comprising at least one trace extending from at least one conductive aperture of the plurality of conductive apertures.

4. The semiconductor package of claim 3, wherein the at least one conductive aperture includes a conductive layer.

5. The semiconductor package of claim 1, wherein the substrate is a first substrate and wherein the semiconductor package further comprises:
a second substrate, comprising:
a third planar surface;
a fourth planar surface opposite the third planar surface;
a third ledge extending from a first lateral side of the second substrate, the third ledge and the third planar surface forming a third stairstep configuration;
a plurality of conductive columns provided on the third ledge;
a fourth ledge extending from a second lateral side of the second substrate, the fourth ledge and the fourth planar surface forming a fourth stairstep configuration; and
a plurality of conductive apertures defined by the fourth ledge.

6. The semiconductor package of claim 5, wherein the plurality of conductive apertures defined by the fourth ledge of the second substrate are mechanically connected and electrically connected to the plurality of conductive columns provided on the first ledge of the first substrate.

7. The semiconductor package of claim 5, wherein the plurality of conductive apertures defined by the second ledge of the first substrate are mechanically connected and electrically connected to the plurality of conductive columns provided on the third ledge of the second substrate.

8. The semiconductor package of claim 5, further comprising at least one electronic component electrically coupled to at least one of the third planar surface and the fourth planar surface.

9. The semiconductor package of claim 8, wherein the at least one electronic component electrically coupled to the at least one of the first planar surface and the second planar surface is a first type of electronic component and wherein the at least one electronic component electrically coupled to the at least one of the third planar surface and fourth planar surface is a second type of electronic component.

10. The semiconductor package of claim 8, wherein the at least one electronic component electrically coupled to the at least one of the first planar surface and the second planar surface is electrically coupled to the at least one electronic component electrically coupled to the at least one of the third planar surface and fourth planar surface.

11. A method, comprising:
providing a first substrate section having a plurality conductive columns on a first lateral side;
providing a second substrate section having a plurality of conductive apertures defined by a second lateral side; and
interconnecting the first substrate section and the second substrate section by inserting the plurality of conductive columns on the first lateral side of the first substrate section into the plurality of conductive apertures defined by the second lateral side of the second substrate section.

12. The method of claim 11, wherein the first substrate section has a first electronic component and the second substrate section has a second electronic component.

13. The method of claim 12, wherein the first electronic component is a first type of electronic component and the second electronic component is a second type of electric component that is different from the first type of electronic component.

14. The method of claim 12, wherein the first electronic component is electrically coupled to the second electronic component.

15. The method of claim 11, wherein the plurality of conductive columns is comprised of a first conducting layer and wherein the plurality of conductive apertures is comprised of a second conducting layer.

16. A semiconductor package, comprising:
a substrate, comprising:
a first ledge extending from a first lateral side, the first ledge and a first planar surface forming a first stairstep portion;
a plurality of first interconnection means extending from the first ledge;
a second ledge extending from a second lateral side, the second ledge and a second planar surface forming a second stairstep portion; and
a plurality of second interconnection means defined by the second ledge; and
at least one electronic component electrically coupled to the substrate.

17. The semiconductor package of claim 16, further comprising a three-dimensional (3D) printed enclosure means at least partially enclosing the at least one electronic component.

18. The semiconductor package of claim 16, further comprising at least one signal routing means extending from at least one of the plurality of first interconnection means.

19. The semiconductor package of claim 16, further comprising at least one signal routing means extending from at least one of the plurality of second interconnection means.

20. The semiconductor package of claim 16, wherein the substrate is a first substrate and wherein the semiconductor package further comprises a second substrate, the second substrate comprising:
a third planar surface;
a fourth planar surface opposite the third planar surface;
a third ledge extending from a first lateral side of the second substrate, the third ledge and the third planar surface forming a third stairstep configuration;
a plurality of conductive columns provided on the third ledge;
a fourth ledge extending from a second lateral side of the second substrate, the fourth ledge and the fourth planar surface forming a fourth stairstep configuration; and
a plurality of conductive apertures defined by the fourth ledge.
